(19) United States
(12) Patent Application Publication
(10) Pub. No.: US 2008/0211569 A1
(43) Pub. Date: Sep. 4, 2008

(54) Higher voltage switch based on a standard process

(76) Inventors: Kelvin Yupak Hui, Fremont, CA (US); Kam-Fai Tang, Irvine, CA (US); Jason Xiao Bo Hu, Shenzhen (CN); Man Sun John Chan, Hong Kong (CN)

Correspondence Address: TROP PRUNER & HU, PC, 1616 S. VOSS ROAD, SUITE 750, HOUSTON, TX, 77057-2631, US

(21) Appl. No.: 11/712,726

(22) Filed: Mar. 1, 2007

(51) Int. Cl. H03K 17/687

(52) U.S. Cl. 327/437

(57) ABSTRACT

A higher voltage switching circuit based on a standard process limits the lowest applied voltage to an intermediate voltage between the higher voltage and ground, instead of ground. In this way, the maximum electric field across the gate dielectric is greatly reduced. In additional the use of p-type triple well also reduces junction breakdown in some embodiments. This concept is also valid in the case where the high voltage is negative, in which case the intermediate voltage is also negative.

### BACKGROUND

This relates to high voltage switching circuits based on a standard process. One application of high voltage switching circuits is for the programming of non-volatile memory arrays, such as Flash, Electrically Erasable Programmable Read Only Memory (EEPROM) and antifuse programming.

Unlike a low voltage switch, a high voltage switch switches between a higher voltage and a lower voltage. The higher voltage can be from an external power supply, or it can be generated on-chip by various charge-pumping methods. Because the higher voltage is usually much higher than the normal power supply, it places a relatively high electric field stress on the transistors.

Normally, standard MOS transistors are built to give the fastest speed. The term “standard” is used to refer to transistors that operate at conventional supply voltages and to processes for making such transistors. Currently, conventional supply voltages are typically from 2.5 to 3.3 volts, although the present invention is not so limited. The gate dielectric thickness is just thick enough to withstand a normal power supply (Vcc) stress for 20 years, and 1.5 times Vcc for a very short period of time. If a higher voltage is applied to such a transistor, even briefly, it may result in oxide rupture and/or junction breakdown.

Therefore, special high voltage tolerant transistors are usually required for high voltage circuits. However the high voltage tolerant transistors require additional masking steps, implantation and oxidation cycles. The added process complexity results in higher wafer cost, lower yield and modified standard transistor characteristics. Therefore, it is very desirable if a higher voltage switch can be built using a standard transistor process without sacrificing reliability.

### BRIEF DESCRIPTION OF THE DRAWINGS

FIG. 1 is a schematic depiction of a non-volatile memory according to one embodiment;

FIG. 2 is a cross-sectional view of an NMOS transistor that is stressed between a higher voltage and an intermediate voltage in accordance with one embodiment;

FIG. 3 is a cross-sectional view of a PMOS transistor that is stressed between a higher voltage and an intermediate voltage in accordance with one embodiment;

FIG. 4 is a modification of the embodiment of FIG. 2 where the NMOS transistor is inside a p-type triple well;

FIG. 5 is a modification of the embodiment of FIG. 1 where the higher voltage is negative relative to ground;

FIG. 6 is a modification of the embodiments of FIGS. 1 and 5, where both a higher positive voltage and a higher negative voltage are applied to a switching circuit;

FIG. 7 is the schematic depiction of one of the implementation of FIG. 1; and

FIG. 8 is the schematic depiction of one of the implementation of FIG. 1 where a p-type triple well is used.

### DETAILED DESCRIPTION

In a CMOS (complementary metal oxide semiconductor) higher voltage switch, some of the nodes within the switch are at a higher voltage (Vpp). Vpp or a higher voltage refers to a voltage higher than the voltage used by standard transistors and relates to voltages high enough to damage standard transistors. A higher voltage may, for example, break down a gate dielectric or produce gate induced drain leakage (GIDL). Currently, Vpp may be from 5 to 7 volts, for example, but the present invention is not so limited.

If all nodes of an NMOS transistor are grounded, except the drain, which is at Vpp, the NMOS transistor may be used as a blocking device to cut off Vpp. The drain-gate overlapping region sees a voltage difference of Vpp. Large tunneling current and dielectric breakdown occurs at the overlapping region if the dielectric electric field is large enough. Another leakage is gate induced drain leakage (GIDL) from drain to substrate.

Alternatively, the gate of the NMOS transistor in a switch may be at Vpp while all the other nodes are at ground. In this case the NMOS transistor is used as a passing device. The full Vpp voltage drop appears across the gate dielectric, resulting in a large tunneling current and possibly dielectric breakdown.

Corresponding bias states exist for a standard PMOS transistor. These biasing conditions may have to be avoided when Vpp is large and only standard MOS transistors are used.

It is advantageous to avoid using non-standard transistors for the higher voltage switches while using standard transistors for all other applications. The need to use two different transistors complicates the fabrication process and increases cost. Using all higher voltage tolerant transistors would adversely affect speed.

Commonly used CMOS latches are not suitable for switching between Vpp and ground. Latch transistors are biased at conditions, as described above. Therefore, the latch may use higher voltage tolerant transistors due to reliability concerns. In general, any higher voltage switching circuit that is biased between Vpp and ground will face the same problem—some of the transistors in the circuit will see the maximum Vpp to ground swing.

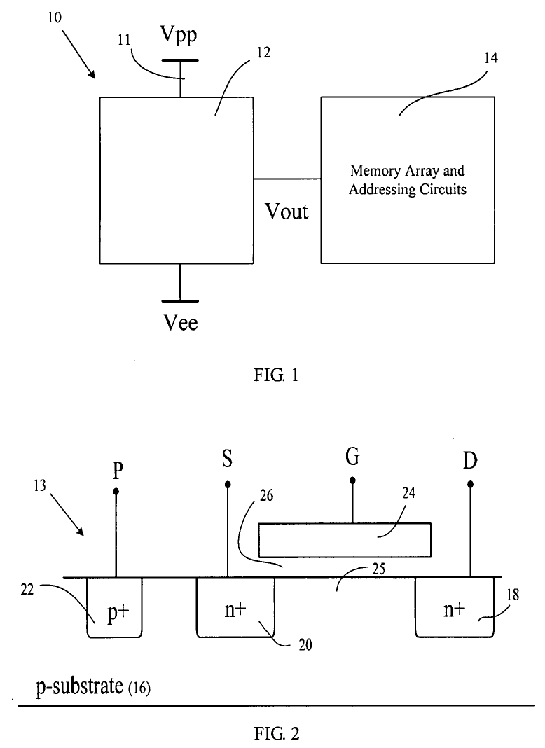

Referring to FIG. 1, the lowest voltage applied to the circuit block 12 (other than the substrate bias 11) is Vee, an intermediate voltage between Vpp and ground. For example, in some embodiments, Vee may be approximately equal to the supply voltage of standard transistors. In other embodiments, Vee may be equal to half of Vpp. Still other embodiments may be used as well.

As a result, the ground to Vee and Vee to Vpp bias voltages fall in the range of the nominal supply voltage of the standard process. The maximum voltage swing for any transistor within the circuit 12 is between Vpp and Vee, which swing is smaller than the swing between Vpp and ground. The output voltage (Vout) also switches between Vpp and Vee. Vee can be biased externally, or generated on-chip by a circuit block, such as a charge pump.

The circuit block 12, shown in FIG. 1, may be a higher to lower voltage switch that switches between the higher voltage and a lower voltage. The lower voltage may then be used by the memory array and addressing circuits 14 of a conventional non-volatile memory, such as a flash memory or an EEPROM, to give a few examples. The memory array may also use the higher voltage, Vpp, for programming and erasing of the cells within the memory array.

Thus, the non-volatile memory 10 may be formed using all standard fabrication processes in one embodiment. In other words, it is not necessary to make special transistors to withstand the adverse affects of the higher voltage Vpp. Instead, by appropriately biasing the circuit 12, the need for special processing may be avoided in some embodiments.

Referring to FIG. 2, a transistor 13 from the circuit block 12 is illustrated. In this case, the transistor 13 is an NMOS transistor. It may be a transistor with a gate 24 receiving a gate bias G, a gate dielectric 26, a channel 25 formed in a p-type substrate 16, a source 20 having a source bias S, and a drain 18 including a drain bias D. A substrate node P may be connected to the substrate by a p+ type contact 22.

The gate 24 is exposed to either Vee or Vpp. The drain may be exposed to Vpp or Vee and the source may be exposed to Vee or a voltage equal to or between Vpp and Vee. Generally, the substrate node P is grounded. In any of these conditions, the gate dielectric 26 is exposed to sufficiently low voltage differences that gate induced drain leakage or substrate breakdown may be avoided. This may be due to the selection of the voltage Vee to avoid such adverse affects. For example, if the drain is at Vpp and the gate is at Vee, the voltage difference may be designed to be in the range of a nominal supply voltage of a standard transistor.

While one or more nodes may be exposed to the higher voltage Vpp, no critical component is ever exposed to a voltage difference of the magnitude of Vpp. This is because the lowest voltage, except for the substrate node P, that is used is Vee. The substrate node P may be grounded. The substrate node P is the node connecting to the P substrate through a p+ terminal 22 to ground. All the other nodes, including the gate to drain, gate to source, and drain to source terminals are exposed to either zero to Vee or Vee to Vpp. Thus, the voltage swing is limited to between Vee and Vpp and none of the nodes S, G, or D go to ground—only the substrate node P goes to ground.

As used herein, transistor bias is a bias voltage applied to the source, drain, or gate of an MOS transistor. Substrate bias is a bias applied to the substrate. Substrate bias may include a bias applied to the substrate itself or any particular well associated with the substrate. Thus, any bias applied directly to the source, gate, or drain is a transistor bias and all other biases may be termed herein substrate bias.

By avoiding a transistor bias less than the intermediate voltage Vee, the voltage differences observed by the transistor nodes will be non-destructive. The lowest transistor bias is Vee in some embodiments.

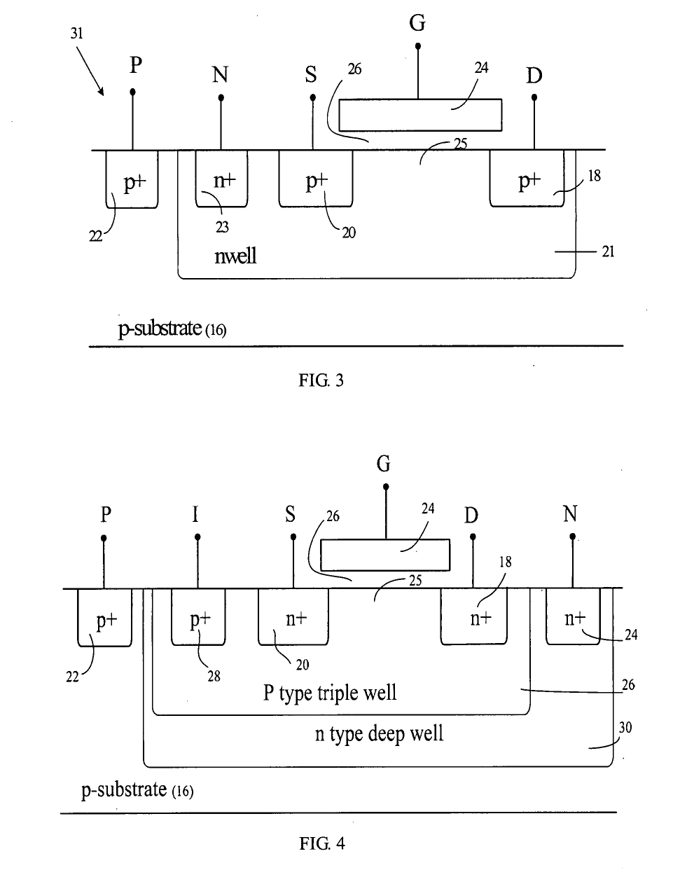

The same considerations apply to the PMOS transistor 31 shown in FIG. 3. It includes an n-well 21 within the p-type substrate 16, in accordance with one standard complementary metal oxide semiconductor (CMOS) fabrication process. It also includes an n-well contact 23. The n-well contact 23 may be exposed to the higher voltage Vpp. But, again, no critical structure within the transistor is exposed to any voltage (i.e. transistor bias) other than zero to Vee or Vpp to Vee.

The maximum electric field across the gate dielectric 26 is reduced. Therefore, a standard transistor with a normal gate dielectric thickness can be used. Since the substrate is grounded, the NMOS junction as well as the gate to substrate will still see a maximum Vpp to ground bias. However, in most situations, the breakdown is limited by gate dielectric or GIDL induced breakdown, both of which depend on the gate dielectric electric field only. The junction breakdown voltage is usually much higher and of a lesser concern. The junction breakdown voltage can also be increased by modifying how the transistor dimensions without changing the fabrication process.

In the case where the junction breakdown is lower than Vpp, a p-type triple well may be used, as shown in FIG. 4. The triple well is made up of a p-type well 30 fully enclosed in a deep n-type well 50 and can be biased via contact 28 to a voltage higher than ground without forward biasing any p-n junction. The most logical, but not necessary, bias voltage for the p-type triple well, is Vee. Again, the substrate node 22 may be grounded, the triple well contact 28 may be at Vee, source S may be equal to or less than Vpp or greater than or equal to Vee, while the gate G is at Vee, the drain D is at Vpp, and the deep n-type well 50 is at Vpp. In this case, the NMOS transistor nodes are not exposed to a voltage difference larger than that between Vpp and Vee.

The same arrangements also apply to the case where the higher voltage is negative (−|Vpp|), as shown in FIG. 5. In this case the intermediate voltage may also be negative (−|Vee|). Except for the polarity of the voltage, all previous situations remain valid except that the potentials Vpp and Vee are switched, as shown in FIG. 5.

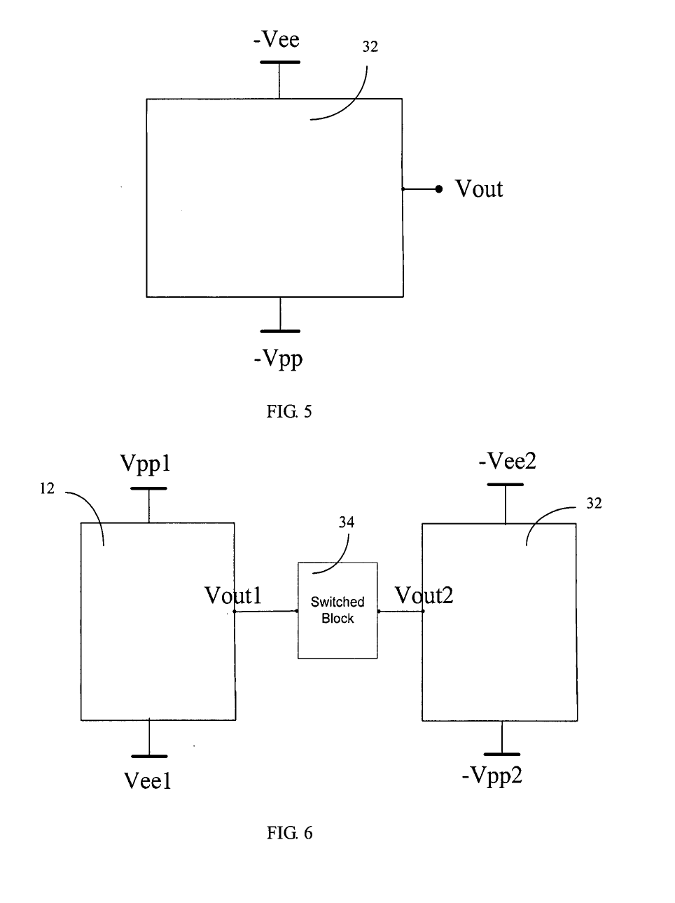

The configurations of circuit blocks 12 and 32, in FIGS. 1 and 5, can be combined together as illustrated in FIG. 6. A switched block 34 may include a memory array that uses both higher positive and negative voltages. In this embodiment, the positive voltage switches between Vpp1 and Vee1, and the negative voltage switches between −Vpp2 and −Vee2.

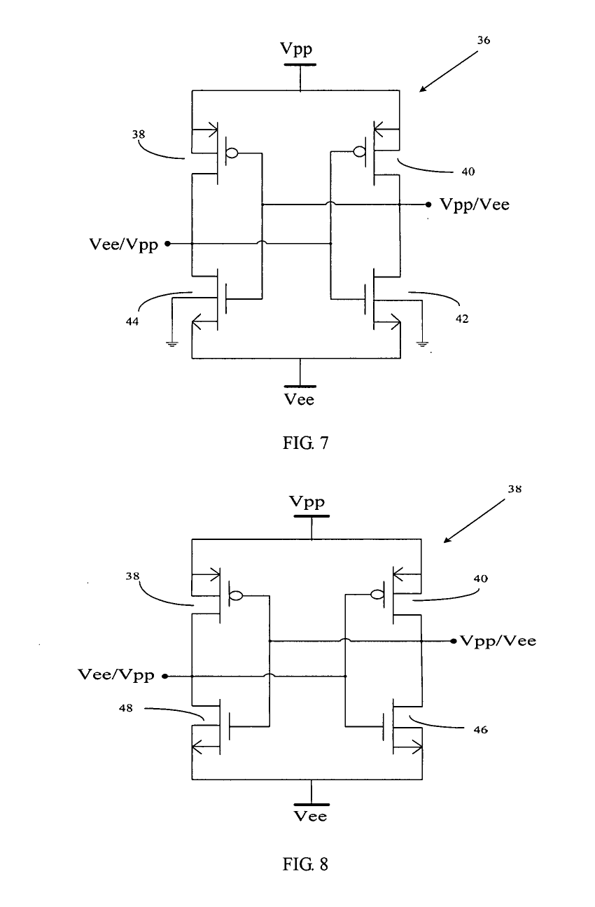

FIG. 7 shows one implementation of the circuit block 12. A CMOS latch 36 is used. However, in this case, the lowest voltage that is applied to the latch 36, other than the substrate node, is Vee. The maximum stressing voltages across the NMOS and PMOS transistors 38, 40, 42, or 44 are the same as described in connection with FIGS. 2 and 3.

The output of the latch 36 is either Vpp or Vee. The latch 36 output does not dip to ground.

Thus, in a CMOS application, a transistor bias is applied to the source 20 of an N-channel MOSFET 44 or 42. The transistor bias includes a first voltage level (e.g., Vee) whose absolute value is greater than ground potential. The gate and drain of the N-channel MOSFETs 42 or 44 switches between the first and a second voltage level (e.g., Vpp) whose absolute value is higher than the first voltage level. The bias on the source, drain, and gate of the P-channel MOSFET 38 or 40 is limited to between the first and second voltage levels. The output of the latch 36 is limited to a level between the first and second voltage levels.

Where a triple well is used, the p-type triple well contact 28 may be at a third voltage level between ground and the first voltage level. The n-type deep well contact may be at a fourth voltage level between the second and third voltage levels. As used herein, “between the voltage levels” defines a range including the two voltage levels.

FIG. 8 is a modification to FIG. 7 where the NMOS transistors 46 and 48 are built inside a p-type triple well. In this case even the drain to substrate voltage difference is limited to that between the higher voltage (Vpp) and the intermediate voltage (Vee). Again, the latch 38 outputs stay between Vpp and Vee, without dipping to ground. The absolute value of output stays higher than ground in both positive and negative Vpp scenarios.

In some embodiments, all of the transistors of the circuit blocks 12 and/or 32 have the same gate dielectric thicknesses. Likewise, all of the NMOS transistors may be made by the same process and all of the PMOS transistors may be made by the same process.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. A method comprising:
providing a voltage switch including N-channel and P-channel MOSFETS;
applying a transistor bias with a first voltage level whose absolute value is greater than ground potential to the source of one of said MOSFETs; and
allowing the gate and drain of said one of said MOSFETs to switch between the first voltage level and a second voltage level whose absolute value is higher than the first voltage level; and
limiting the biases to the source, drain, and gate of the other of said MOSFETs to between the first voltage level and said second voltage level.

2. The method of claim 1 including limiting the output of the switch to between the first and second voltage levels.

3. The method of claim 2 including limiting the maximum voltage difference from source to gate, and from drain to gate of all transistors inside the said switching circuit to no more than that between the second voltage level and the first voltage level.

4. The method of claim 2 including causing the output of said switch to stay at or above the first voltage level.

5. The method of claim 1 including using a triple well.

6. The method of claim 5 including using a p-type triple well contact at a third voltage level between ground level and said first voltage level and an n-type deep well contact at a fourth voltage level between the second and third voltage levels.

7. The method of claim 2 including using negative first and second voltage levels.

8. The method of claim 7 including providing two switching circuits, one using positive voltages and the other using negative voltages.

9. The method of claim 1 including providing a circuit in the form of a latch.

10. The method of claim 9 including providing a CMOS latch including a p-type triple well.

11. The method of claim 3 including using the same gate dielectric thickness for all of said transistors.

12. A high voltage switch comprising:
an N-channel and a P-channel MOSFET, each having a gate, source, and drain;
a transistor bias with a first voltage level whose absolute value is greater than ground potential applied to the source of one of said MOSFETs; and
the gate and drain of the other of said MOSFETs to switch between the first voltage level and a second voltage level whose absolute value is higher than said first voltage level, a transistor bias to the source, drain, and gate of the other of said MOSFETs between the first and second voltage levels.

13. The switch of claim 12 wherein the MOSFETs have a maximum voltage difference from source to gate and from drain to gate of no more than the difference between the maximum voltage and said intermediate voltage.

14. The switch of claim 12 wherein the output of said switch stays between the first and second voltage levels.

15. The switch of claim 12 including a triple well.

16. The switch of claim 15 including a p-type triple well contact at a third voltage level between ground and said first voltage level and an n-type deep well contact at a fourth voltage level between the second and third voltage levels.

17. The switch of claim 13 including a negative first and second voltage level.

18. The switch of claim 17 including two switches, one using positive voltages and the other using negative voltages.

19. The switch of claim 12 wherein said switch is a latch.

20. The switch of claim 19 wherein said switch is a CMOS latch with a p-type triple well.

21. The switch of claim 20 wherein all of the transistors of said switch have the same gate dielectric thickness.

22. The switch of claim 12 including a non-volatile memory array coupled to said switch.
